(19) United States
(12) Patent Application Publication
(10) Pub. No.: US 2009/0028217 A1
(43) Pub. Date: Jan. 29, 2009

(54) Ultra-wideband (UWB) frequency synthesizer system and method

(75) Inventors: Chao-Shiun Wang, Hsinchu (TW); Chorng-Kuan Wang, Hsinchu (TW); Horng-Yuan Shih, Hsinchu (TW); Zhi-Wei Wang, Hsinchu (TW); Kai-Cheung Juang, Hsinchu (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Industrial Technology Research Institute

(21) Appl. No.: 11/878,581

(22) Filed: Jul. 25, 2007

(51) Int. Cl. H04B 1/69; H03B 21/00

(52) U.S. Cl. 375/130; 327/105; 375/E01.001

(57) ABSTRACT

An ultra-wideband (UWB) frequency synthesizer is provided for use in UWB communication. The UWB frequency synthesizer may include a first section and a second section. The first section may be configured to generate a first plurality of frequencies. The second section may be coupled to the first section and configured to generate a second plurality of frequencies respectively corresponding to individual channels of UWB bandwidth based upon the first plurality of frequencies. Further, the first section is configured to include a voltage-controlled oscillator (VCO) providing a base frequency fvco corresponding to the UWB bandwidth, and to generate the first plurality of frequencies based on a single phase-locked loop (PLL) and a reference frequency provided to the single PLL based on the base frequency fvco.

### TECHNICAL FIELD

The present invention relates generally to ultra-wideband (UWB) communication devices and, more particularly, to UWB frequency synthesizer techniques.

### BACKGROUND

Recent developments in ultra-wideband (UWB) technology have found use in radio communication systems primarily in a frequency bandwidth from 3.1 GHz to 10.6 GHz. UWB radios communicate with short pulses or cycles on the order of nanoseconds, spreading energy over a wide range of bandwidth. Currently available high frequency and large bandwidths of UWB radios may potentially provide high speed data communication and other applications. However, due to UWB's unlicensed use and wide spectrum, interference between different UWB radios may be present during communication and may have an adverse impact on communication quality between UWB radios.

To minimize the impact of the interference, UWB applications often use direct sequence spread spectrum technology or frequency hopping technology by orthogonal frequency division multiplexing (OFDM). Since these technologies, when used in the UWB applications, often require a group of wide-band channels or frequencies, both the radio transmitter and the radio receiver (radio transceivers) may need multiple frequency synthesizers and/or multiple phase lock loops (PLLs) to implement these technologies.

However, when multiple PLLs voltage-controlled oscillators (VCOs), and/or single sideband (SSB) mixers are used, interference between these devices and/or between different channels in the group may affect operational quality of the radio transceivers. Further, when frequency synthesizers are implemented using large-scale integration (LSI) technology, multiple PLLs or VCOs may increase complexity of circuit design and may also increase the die size and cost of the integrated circuit implementing the frequency synthesizers.

Methods and systems consistent with certain features of the disclosed embodiments address one or more of the problems set forth above.

### SUMMARY

One aspect of the present invention includes an ultra-wideband (UWB) frequency synthesizer. The UWB frequency synthesizer may include a first section and a second section. The first section may be configured to generate a first plurality of frequencies. The second section may be coupled to the first section and configured to generate a second plurality of frequencies respectively corresponding to individual channels of UWB bandwidth based upon the first plurality of frequencies. Further, the first section is configured to include a voltage-controlled oscillator (VCO) providing a base frequency fvco corresponding to the UWB bandwidth, and to generate the first plurality of frequencies based on a single phase-locked loop (PLL) and a reference frequency provided to the single PLL based on the base frequency fvco.

Another aspect of the present invention includes an ultra-wideband (UWB) terminal. The UWB terminal may include a UWB transceiver for transmitting and receiving UWB signals for the UWB communication. The UWB terminal may include a UWB frequency synthesizer, and the UWB frequency synthesizer may further include a first section and a second section. The first section may be configured to generate a first plurality of frequencies. The second section may be coupled to the first section and configured to generate a second plurality of frequencies respectively corresponding to individual channels of UWB bandwidth based upon the first plurality of frequencies. Further, the first section is configured to include a voltage-controlled oscillator (VCO) providing a base frequency fvco corresponding to the UWB bandwidth, and to generate the first plurality of frequencies based on a single phase-locked loop (PLL) and a reference frequency provided to the single PLL based on the base frequency fvco.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments consistent with the invention and together with the description, serve to explain the principles of the invention.

FIG. 1 shows an exemplary ultra-wideband (UWB) communication network incorporating certain features of the present invention;

FIG. 2 shows exemplary channel groups and individual channels with corresponding base frequency consistent with the present invention;

FIG. 3 shows a functional block diagram of an exemplary UWB frequency synthesizer consistent with the present invention;

FIG. 4 shows a block diagram of an exemplary intermediate frequency generation section consistent with the present invention; and

FIG. 5 shows a block diagram of an exemplary frequency integration and output section consistent with the present invention.

### DETAILED DESCRIPTION

Reference will now be made in detail to embodiments of the invention, examples of which are illustrated in the accompanying drawings. Wherever possible, the same reference numbers will be used throughout the drawings to refer to the same or like parts.

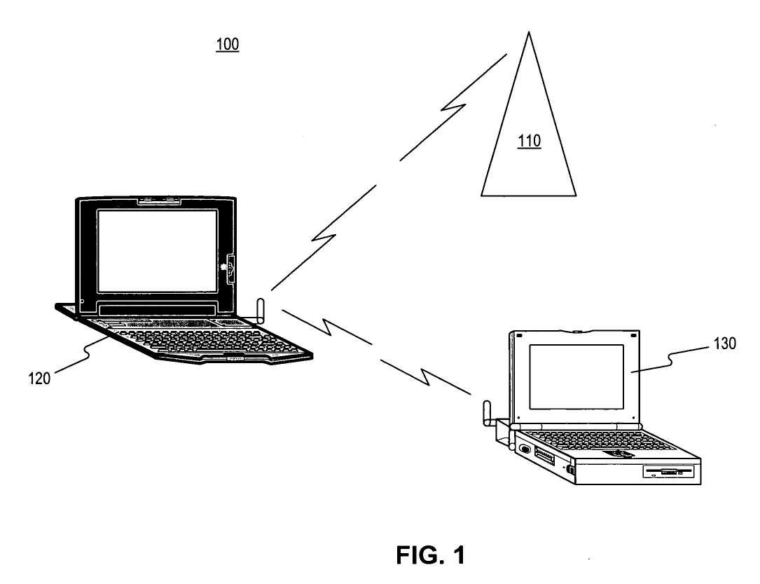

FIG. 1 shows an exemplary ultra-wideband (UWB) communication network 100. As shown in FIG. 1, UWB communication network 100 may include a base station 110, a first communication terminal 120, and a second communication terminal 130. The number of base stations and communication terminals is exemplary only and not intended to be limiting. Any number of base stations and communication terminals may be used without departing from the principles of the present invention.

Base station 110 may be any appropriate type of UWB base station, such as a land based communication base station or a satellite based communication device. Communication terminal 120 may be any appropriate UWB communication terminal capable of communicating with base station 110 in the UWB frequency band. Communication terminal 120 may also be configured to communicate with other communication terminals, such as communication terminal 130, directly or indirectly via base station 110. Communication terminals 120 and/or 130 may be provided with a UWB transceiver (i.e., transmitter and receiver) to enable the communication between each other or between the terminals and base station 110.

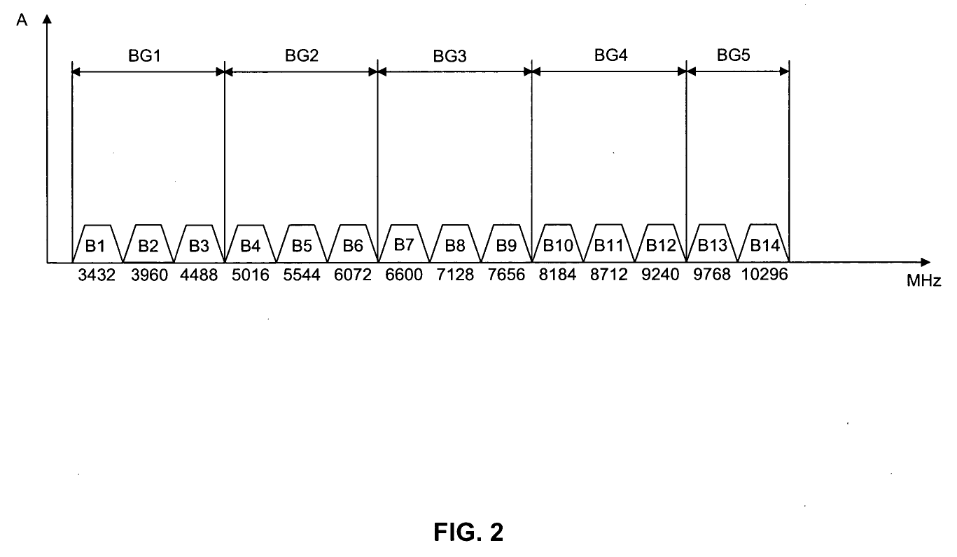

The UWB radio transceiver (not shown) that may be provided in communication terminal 120 and/or 130 may be implemented by using direct sequence code division multiple access (DS-CDMA) and/or multi-band orthogonal frequency division multiplexing (MB-OFDM) technologies. The UWB radio transceiver may use multiple groups of channels over the entire UWB bandwidth (i.e., 3.1 GHz to 10.6 GHz) for transmitting and receiving modulated signals. Each channel may be represented by a frequency band, and a number of continuous channels may be represented by a frequency band group. FIG. 2 shows exemplary channel groups and individual channels with corresponding base frequency.

As shown in FIG. 2, the UWB radio transceiver may use frequency bands B1-B14 grouped in frequency band groups BG1-BG5. Frequency band group BG1 may include frequency band B1, with a base frequency of approximately 3,432 MHz; frequency band B2, with a base frequency of approximately 3,960 MHz; and frequency band B3, with a base frequency of approximately 4,488 MHz. Frequency band group BG2 may include frequency band B4, with a base frequency of approximately 5,016 MHz; frequency band B5, with a base frequency of approximately 5,544 MHz; and frequency band B6, with a base frequency of approximately 6,072 MHz. Frequency band group BG3 may include frequency band B7, with a base frequency of approximately 6,600 MHz; frequency band B8, with a base frequency of approximately 7,128 MHz; and frequency band B9, with a base frequency of approximately 7,656 MHz. Further, frequency band group BG4 may include frequency band B10, with a base frequency of approximately 8,184 MHz; frequency band B11, with a base frequency of approximately 8,712 MHz; and frequency band B12, with a base frequency of approximately 9,240 MHz. Frequency band group BG5 may include frequency band B13, with a base frequency of approximately 9,768 MHz; and frequency band B14, with a base frequency of approximately 10,296 MHz. Other frequency groups and/or frequency band, however, may also be used.

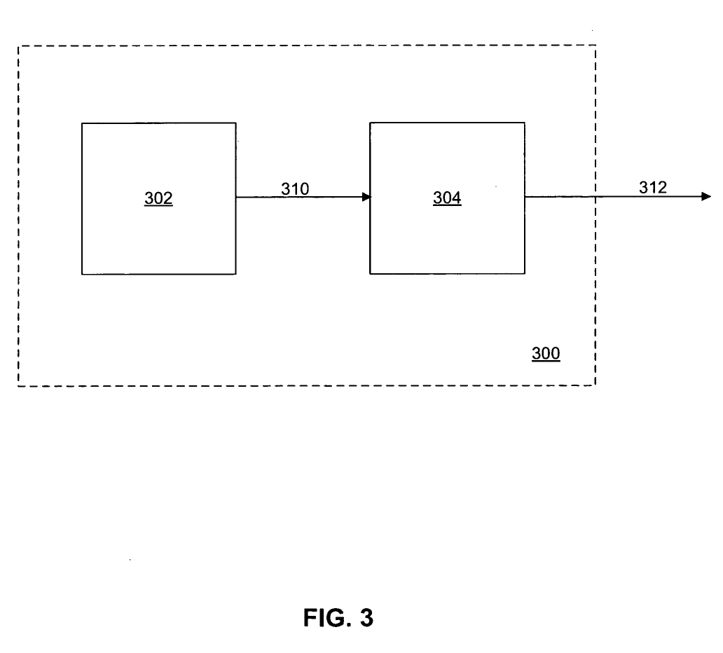

Further, the UWB transceiver may include a UWB frequency synthesizer to generate frequency bands B1-B14 to generate carrier waves for UWB communications. FIG. 3 shows a functional block diagram of an exemplary UWB frequency synthesizer 300 consistent with the present invention. As shown in FIG. 3, synthesizer 300 may include an intermediate frequency generation section 302 and a frequency integration and output section 304. Intermediate frequency generation section 302 may generate intermediate frequencies 310 and may provide the generated intermediate frequencies 310 to frequency integration and output section 304. The term “frequency,” as used herein, may refer to the actual value of the frequency of a particular waveform signal, or the particular waveform signal itself. An intermediate frequency may refer to a frequency to be used to create or derive a final output frequency.

Further, frequency integration and output section 304 may provide output frequencies 312 over the entire bandwidth of the UWB frequency, e.g., frequency bands B1-B14, etc., to be used by the UWB transceiver. It is understood that the number of specified components is exemplary only and not intended to be limiting. Certain components may be removed, other components may be added, and the number of components may be changed without departing from the principle and scope of the present invention.

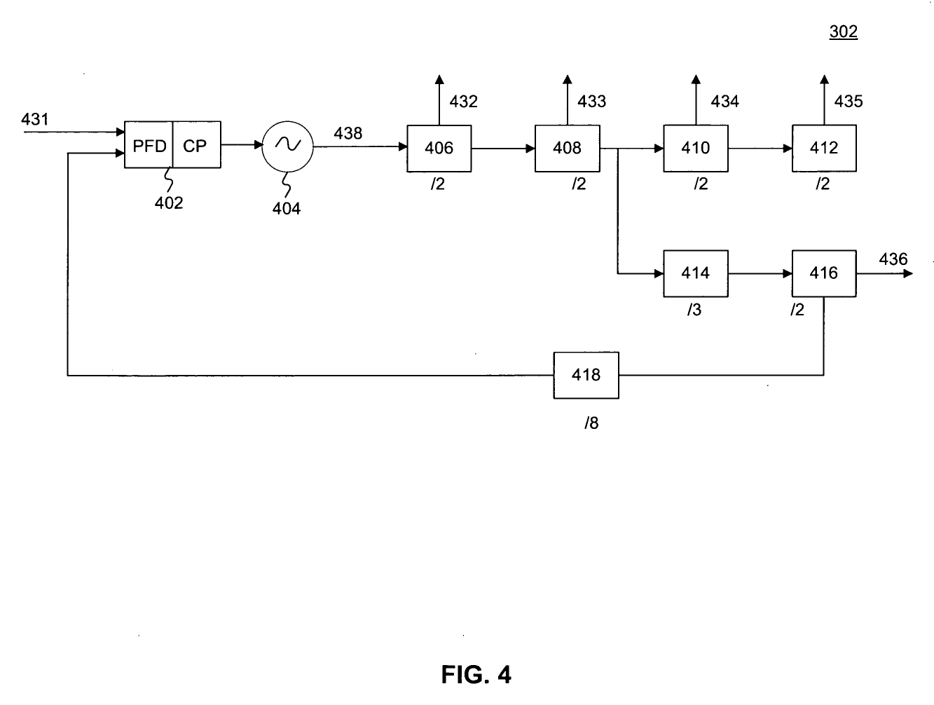

Intermediate frequency generation section 302 may include any appropriate circuitry to synthesize and generate UWB frequencies. Intermediate frequency generation section 302 may be implemented by using discrete devices or LSI devices or a combination thereof. FIG. 4 shows a block diagram of an exemplary intermediate frequency generation section 302.

As shown in FIG. 4, intermediate frequency generation section 302 may include a phase/frequency detector (PFD) and charge pump (CP) 402, referred to herein as PFD/CP 402, a voltage-controlled oscillator (VCO) 404, and dividers 406, 408, 410, 412, 414, 416, and 418. An input reference frequency 431 may be provided to PFD/CP 402 as input to intermediate frequency generation section 302. And intermediate frequency generation section 302 may generate various intermediate frequencies 432, 433, 434, 435, and 436, etc. Further, PFD/CP 402, VCO 404, and certain dividers, e.g., dividers 406, 408, 414, 416, and 418, etc., may form a phase-locked loop (PLL) circuitry such that intermediate frequencies 432-436 may remain coherent to reference frequency 431.

To form the PLL circuitry, PFD/CP 402 may be coupled with VCO 404 to generate a base frequency 438. Base frequency 438 may be chosen to correspond to the UWB frequency bandwidth. VCO 404 may be coupled with divider 406 such that base frequency 438 may be used or divided to provide intermediate frequency 432. Further, divider 406 may be coupled to divider 408 such that the divided frequency from divider 406 may be further divided by divider 408 to provide intermediate frequency 433. Divider 408 may also be coupled separately to divider 410 and divider 414. The divided frequency from divider 408 may be further divided by divider 410 to provide intermediate frequency 434; and may also be further divided by divider 414 and divider 416 to provide intermediate frequency 436. Divider 410 may also be coupled to divider 412 and the divided frequency from divider 410 may be further divided by divider 412 to provide intermediate frequency 435.

Although divider 414 and divider 416 are shown as separate devices, one single divider may be used to provide the same functionality. Further, divider 416 may be coupled to divider 418, and divider 418 may be coupled to PFD/CP 402 to form a closed PLL loop. The divided frequency from divider 416 may be further divided by divider 418 and the divided frequency from divider 418 may be provided to PFD/CP 402 as a feedback. It is understood that the configuration shown in FIG. 4 is for exemplary purpose, and other configurations may also be used.

Reference frequency 431 may include a stable and low-noise constant-frequency signal from a reliable frequency source, such as a crystal oscillator. Reference frequency 431 may be provided from the frequency source directly or may be further processed before being provided to PFD/CP 402. Further, PFD/CP 402 may include any appropriate circuitry providing functionalities of a phase detector and charge pump. Although PFD/CP 402 is shown as a combined device of the phase detector and charge pump, separate devices for the phase detector and the charge pump may also be used. Further, VCO 404 may include any appropriate voltage-controlled oscillator capable of generating a frequency based on a control voltage, or a tuning voltage, applied to VCO 404.

In UWB frequency synthesizing operation, a phase/frequency detector of PFD/CP 402 may detect a phase error between reference frequency 431 and a feedback frequency, via the PLL loop, corresponding to base frequency 438 generated by VCO 404 and may also produce an error voltage that is approximately linear over the range of the phase error, e.g., ±2*π. A charge pump of PFD/CP 402 may create a control or tuning voltage based on the error voltage to control VCO 404 such that base frequency 438 is coherent to reference frequency 431, i.e., without a phase error or with a substantially small amount of phase error.

Dividers 406, 408, 410, 412, 414, 416, and 418 may include any types of appropriate frequency dividers, such as digital dividers or analog dividers. Divider ratios of dividers 406, 408, 410, 412, 414, 416, and 418 may be calculated or predetermined to provide appropriate frequency values for intermediate frequencies 432, 433, 434, 435, and 436. As explained above, certain dividers, e.g., dividers 406, 408, 414, 416, and 418, may be included in the PLL loop to provide the feedback frequency to PFD/CP 402 to set appropriate control or tuning voltages.

Based on particular UWB applications, certain configurations may be used to provide intermediate frequencies 432, 433, 434, 435, and 436 corresponding to frequency bands B1-B14 and frequency band groups BG1-BG5. For example, in certain embodiments, reference frequency 431 may be a frequency of 66 MHz, and base frequency 438 generated by VCO 404 may be a frequency of 12,672 MHz. Further, divider ratios of dividers 406, 408, 410, 412, 414, 416, and 418 may be 2, 2, 2, 2, 3, 2, and 8, respectively. Therefore, based on base frequency 438, generated intermediate frequency 432 may be a frequency of 6,336 MHz (base frequency 438 divided by 2, or one half of base frequency 438); intermediate frequency 433 may be a frequency of 3,168 MHz (base frequency 438 divided by 2 and further divided by 2, or one fourth of base frequency 438); intermediate frequency 434 may be a frequency of 1,584 MHz (base frequency 438 divided by 2, 2, and 2 consecutively, or one eighth of base frequency 438); intermediate frequency 435 may be a frequency of 792 MHz (base frequency 438 divided by 2, 2, 2, and 2 consecutively, or one sixteenth of base frequency 438); and intermediate frequency 436 may be a frequency of 528 MHz (base frequency 438 divided by 2, 2, 3, and 2 consecutively, or one twenty-fourth of base frequency 438). Other frequency values, however, may also be used.

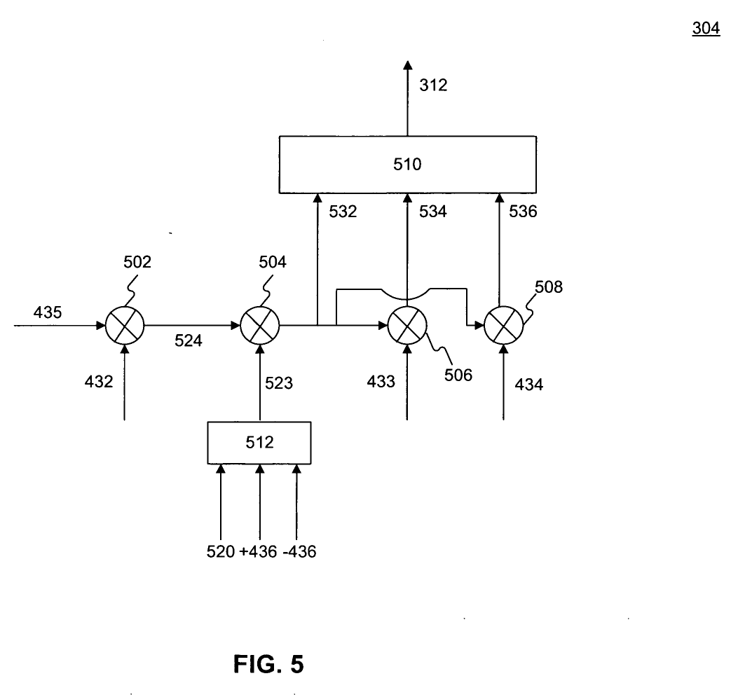

Returning to FIG. 3, after intermediate frequencies 310, e.g., intermediate frequencies 432, 433, 434, 435, and 436, etc., are generated, intermediate frequencies 310 may be provided to frequency integration and output section 304 to generate frequency bands B1-B14 and frequency band groups BG1-BG5. FIG. 5 shows a block diagram of an exemplary frequency integration and output section 304.

As shown in FIG. 5, frequency integration and output section 304 may include a mixer 502, a mixer 504, a mixer 506, a mixer 508, an output buffer 510, and a multiplexer (MUX) 512. Mixers 502, 504, 506, and 508 may include any types of appropriate frequency mixer devices capable of performing the task of frequency conversion by multiplying two frequency signals, which may result in a sum frequency and a difference frequency, and may provide one of the sum or difference frequency to other devices. For example, mixers 502, 504, 506, and 508 may include single-side band (SSB) mixers providing the sum frequency on respective intermediate frequency (IF) ports based on frequencies provided on respective radio frequency (RF) ports and local oscillator (LO) ports and may apply filters to discard one of the sum frequency or the difference frequency. Mixers 502, 504, 506, and 508 may also include double-side band (DSB) mixers providing both the sum frequency and the difference frequencies on the IF ports.

In certain embodiments, intermediate frequency 435 (792 MHz or 1/16 of base frequency 438) may be provided on an RF port of mixer 502, and intermediate frequency 432 (6,336 MHz or ½ of base frequency 438) may be provided on a LO port of mixer 502. Mixer 502 may generate a derivative frequency 524 of 7,128 MHz or 9/16 of base frequency 438, as the sum of intermediate frequencies 435 and 432, and may provide derivative frequency 524 on an IF port of mixer 502. Further, the IF port of mixer 502 may be coupled to an RF port of mixer 504. An output frequency from MUX 512 may be provided on a LO port of mixer 504 to be mixed with derivative frequency 524.

MUX 512 may include any appropriate type of multiplexer, such as a 1:4 MUX or a 1:8 MUX, etc. Output frequency 523 may be chosen as one of input frequencies of: a direct current (DC) frequency 520 (0 Hz), a positive form of intermediate frequency 436 (+528 MHz or + 1/24 of base frequency 438), and a negative form of intermediate frequency 436 (−528 MHz or − 1/24 of base frequency 438). By setting proper control over MUX 512, output frequency 523 may be one of 0 Hz, +528 MHz, or −528 MHz. Also, by switching among the input frequencies of MUX 512, mixer 504 may be provided with all input frequencies of 0 Hz, +528 MHz, or −528 MHz on the LO port.

Further, mixer 504 may provide different frequencies on an IF port of mixer 504 corresponding to the different input frequencies of MUX 512. For example, mixer 504 may provide a frequency of 6,600 MHz or ( 9/16− 1/24) of base frequency 438, a frequency of 7,128 MHz or 9/16 of base frequency 438, and a frequency of 7,656 MHz or ( 9/16+ 1/24) of base frequency 438 corresponding to input frequencies of −528 MHz, 0 Hz, and +528 MHz, respectively, based on derivative frequency 524 (7,128 MHz). Further, the IF port of mixer 504 may be coupled to output buffer 510 to provide group frequencies 532 (6,600 MHz, 7,128 MHz, and 7,656 MHz) corresponding to frequency band group BG3. Group frequencies 532 may also be represented as ( 9/16− 1/24), 9/16, and ( 9/16+ 1/24) of base frequency 438.

The IF port of mixer 504 may also be coupled to an RF port of mixer 506 and to an RF port of mixer 508 to provide the different frequencies of 6,600 MHz, 7,128 MHz, and 7,666 MHz. Further, intermediate frequency 433 (3,168 MHz or ¼ of base frequency 438) may be provided on a LO port of mixer 506, and intermediate frequency 434 (1,584 MHz or ⅛ of base frequency 438) may be provided on a LO port of mixer 508.

Based on the frequencies provided on the RF port and the frequency provided on LO port, mixer 506 may, being used as an SSB mixer, provide on an IF port of mixer 506 a frequency of 3,432 MHz (( 5/16− 1/24) of base frequency 438), a frequency of 3,960 MHz ( 5/16 of base frequency 438), and a frequency of 4,488 MHz (( 5/16+ 1/24) of base frequency 438), corresponding to frequencies of −528 MHz, 0 Hz, and +528 MHz, respectively, as side band frequency one, and a frequency of 9,768 MHz (( 13/16− 1/24) of base frequency 438), a frequency of 10,296 MHz ( 13/16 of base frequency 438), corresponding to frequencies of −528 MHz and 0 Hz, respectively, as the other side band frequency. The IP port of mixer 506 may be coupled to output buffer 510 to provide group frequencies 534 (3,432 MHz, 3,960 MHz, and 4,488 MHz, and 9,768 MHz and 10,296 MHz) corresponding to frequency band group BG1 and frequency band group BG5, respectively. Group frequencies 534 may also be represented as ( 5/16− 1/24), 5/16, ( 5/16+ 1/24), ( 13/16− 1/24), and 13/16 of base frequency 438.

Further, based on the frequencies provided on its RF port and the frequency provided on its LO port, mixer 508 may, being used as an SSB mixer, provide on an IF port of mixer 508 a frequency of 5,016 MHz or ( 7/16− 1/24) of base frequency 438, a frequency of 5,544 MHz or 7/16 of base frequency 438, and a frequency of 6,072 MHz or ( 7/16+ 1/24) of base frequency 438, corresponding to frequencies of −528 MHz, 0 Hz, and +528 MHz, respectively, as side band frequency one, and a frequency of 8,184 MHz or ( 11/16− 1/24) of base frequency 438, a frequency of 8,712 MHz or 11/16 of base frequency 438, and a frequency of 9,240 MHz or ( 11/16+ 1/24) of base frequency 438, corresponding to frequencies of −528 MHz, 0 Hz, and +528 MHz, respectively, as the other side band frequency. The IF port of mixer 508 may be coupled to output buffer 510 to provide group frequencies 536 (5,016 MHz, 5,544 MHz, and 6,072 MHz, and 8,184 MHz, 8,712 MHz, and 9,240 MHz) corresponding to frequency band group BG2 and frequency band group BG4, respectively. Group frequencies 534 may also be represented as ( 7/16− 1/24), 7/16, ( 7/16+ 1/24), ( 11/16− 1/24), 11/16, and ( 11/16+ 1/24) of base frequency 438.

Output buffer 510 may include any appropriate type of device providing output and buffer functionalities. Output buffer 510 may arrange and process all or part of the frequencies received from mixer 504, mixer 506, and mixer 508 to provide UWB frequency bands, i.e., B1-B14, as output frequencies 312. More specifically, mixer 504 may provide frequencies B7-B9 (6,600 MHz, 7,128 MHz, and 7,656 MHz); mixer 506 may provide frequencies B1-B3 and B13-B14 (3,432 MHz, 3,960 MHz, 4,488 MHz, 9,768 MHz, and 10,296 MHz); and mixer 508 may provide frequencies B4-B6 and B10-B12 (5,016 MHz, 5,544 MHz, 6,072 MHz, 8,184 MHz, 8,712 MHz, and 9,240 MHz). Output buffer 510 may also buffer certain frequencies of group frequencies 532, 534, and 536 such that UWB frequency bands B1-B14 may be provided as output frequencies 312 simultaneously.

By using a single PLL loop framework to produce frequency bands over the entire UWB bandwidth, interference and noise among circuit components may be significantly lowered and the die size and manufacturing cost of the UWB frequency synthesizer may be significantly reduced. Further, the disclosed dividers may be used both as part of the closed PLL feedback loop and as part of circuitry providing and calculating intermediate frequencies, with the result that the complexity of the UWB frequency synthesizer may be further reduced.

Further, by using four mixers coupled with the single PLL loop circuitry, a wide range of frequencies may be generated efficiently to cover the entire UWB bandwidth. These disclosed configurations may provide efficient, simple, and cost effective solutions to providing UWB frequency synthesizers. It is understood that the particular values for group frequencies are exemplary only, other group frequencies may be used without departing from the principles of the present invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An ultra-wideband (UWB) frequency synthesizer, comprising:
a first section configured to generate a first plurality of frequencies; and
a second section coupled to the first section and configured to generate a second plurality of frequencies respectively corresponding to individual channels of UWB bandwidth based upon the first plurality of frequencies,
wherein the first section is configured to include a voltage-controlled oscillator (VCO) providing a base frequency fvco corresponding to the UWB bandwidth, and to generate the first plurality of frequencies based on a single phase-locked loop (PLL) and a reference frequency provided to the single PLL based on the base frequency fvco.

2. The UWB frequency synthesizer according to claim 1, wherein the second section includes:
a plurality of side band frequency mixers configured to generate the second plurality of frequencies based on the first plurality of frequencies;
a multiplexer coupled to one of the plurality of side band frequency mixers to provide a variable frequency to the one of the plurality of side band frequency mixers; and
an output buffer coupled to one or more of the plurality of side band frequency mixers to receive the second plurality of frequencies to provide the second plurality of frequencies as output frequencies of the UWB synthesizer simultaneously.

3. The UWB frequency synthesizer according to claim 1, wherein the second plurality of frequencies include ( 5/16− 1/24)*fvco, ( 5/16)*fvco, ( 5/16+ 1/24)*fvco, ( 7/16− 1/24)*fvco, ( 7/16)*fvco, ( 7/16+ 1/24)*fvco, ( 9/16− 1/24)*fvco, ( 9/16)*fvco, ( 9/16+ 1/24)*fvco, ( 11/16− 1/24)*fvco, ( 11/16)*fvco, ( 11/16+ 1/24)*fvco, ( 13/16− 1/24)*fvco, and ( 13/16)*fvco.

4. The UWB frequency synthesizer according to claim 2, wherein the plurality of side band frequency mixers are coupled with one another such that a plurality of frequency groups including the second plurality of frequencies are provided to the output buffer by the plurality of side band frequency mixers based upon the first plurality of frequencies and the variable frequency.

5. The UWB frequency synthesizer according to claim 4, wherein the plurality of frequency groups include:
a first frequency group including ( 9/16− 1/24)*fvco, ( 9/16)*fvco, and ( 9/16+ 1/24)*fvco;
a second frequency group including ( 5/16− 1/24)*fvco, ( 5/16)*fvco, ( 5/16+ 1/24)*fvco, ( 13/16− 1/24)*fvco, and ( 13/16)*fvco; and
a third frequency group including ( 7/16− 1/24)*fvco, ( 7/16)*fvco, ( 7/16+ 1/24)*fvco, ( 11/16− 1/24)*fvco, ( 11/16)*fvco, ( 11/16+ 1/24)*fvco.

6. The UWB frequency synthesizer according to claim 2, wherein the variable frequency includes one of −( 1/24)*fvco, 0 Hz, and +( 1/24)*fvco.

7. The UWB frequency synthesizer according to claim 1, wherein the PLL loop further includes:
a phase/frequency detector and charge pump configured to detect a phase error between the base frequency fvco and the reference frequency, and to control the VCO based on the detected phase error such that the base frequency fvco and the reference frequency are coherent; and
a plurality of frequency dividers configured to provide the first plurality of frequencies based on the base frequency fvco,
wherein the plurality of frequency dividers are coupled to the VCO and the phase/frequency detector and charge pump to form the PLL.

8. The UWB frequency synthesizer according to claim 1, wherein:
the reference frequency is approximately 66 MHz; and
the base frequency fvco is approximately 12,672 MHz.

9. The UWB frequency synthesizer according to claim 1, wherein the first plurality of frequencies include (½)*fvco, (¼)*fvco, (⅛)*fvco, ( 1/16)*fvco, and ( 1/24)*fvco.

10. The UWB frequency synthesizer according to claim 1, wherein the UWB synthesizer is implemented as a large-scale integration (LSI) device.

11. An ultra-wideband (UWB) terminal, comprising:
a UWB transceiver for transmitting and receiving UWB signals for the UWB communication, wherein the UWB terminal includes a UWB frequency synthesizer, and the UWB frequency synthesizer further includes:
a first section configured to generate a first plurality of frequencies; and
a second section coupled to the first section and configured to generate a second plurality of frequencies respectively corresponding to individual channels of UWB bandwidth based upon the first plurality of frequencies,
wherein the first section is configured to include a voltage-controlled oscillator (VCO) providing a base frequency fvco corresponding to the UWB bandwidth, and to generate the first plurality of frequencies based on a single phase-locked loop (PLL) and a reference frequency provided to the single PLL based on the base frequency fvco.

12. The UWB terminal according to claim 11, wherein the second section includes:
a plurality of side band frequency mixers configured to generate the second plurality of frequencies based on the first plurality of frequencies;
a multiplexer coupled to one of the plurality of side band frequency mixers to provide a variable frequency to the one of the plurality of side band frequency mixers; and
an output buffer coupled to one or more of the plurality of side band frequency mixers to receive the second plurality of frequencies to provide the second plurality of frequencies as output frequencies of the UWB synthesizer simultaneously.

13. The UWB terminal according to claim 11, wherein the second plurality of frequencies include ( 5/16− 1/24)*fvco, ( 5/16)*fvco, ( 5/16+ 1/24)*fvco, ( 7/16− 1/24)*fvco, ( 7/16)*fvco, ( 7/16+ 1/24)*fvco, ( 9/16− 1/24)*fvco, ( 9/16)*fvco, ( 9/16+ 1/24)*fvco, ( 11/16− 1/24)*fvco, ( 11/16)*fvco, ( 11/16+ 1/24)*fvco, ( 13/16− 1/24)*fvco, and ( 13/16)*fvco.

14. The UWB terminal according to claim 12, wherein the plurality of side band frequency mixers are coupled with one another such that a plurality of frequency groups including the second plurality of frequencies are provided to the output buffer by the plurality of side band frequency mixers based upon the first plurality of frequencies and the variable frequency.

15. The UWB terminal according to claim 14, wherein the plurality of frequency groups include:
a first frequency group including ( 9/16− 1/24)*fvco, ( 9/16)*fvco, and ( 9/16+ 1/24)*fvco;
a second frequency group including ( 5/16− 1/24)*fvco, ( 5/16)*fvco, ( 5/16+ 1/24)*fvco, ( 13/16− 1/24)*fvco, and ( 13/16)*fvco; and
a third frequency group including ( 7/16− 1/24)*fvco, ( 7/16)*fvco, ( 7/16+ 1/24)*fvco, ( 11/16− 1/24)*fvco, ( 11/16)*fvco, ( 11/16+ 1/24)*fvco.

16. The UWB terminal according to claim 12, wherein the variable frequency includes one of −( 1/24)*fvco, 0 Hz, and +( 1/24)*fvco.

17. The UWB terminal according to claim 11, wherein the PLL loop further includes:
a phase/frequency detector and charge pump configured to detect a phase error between the base frequency fvco and the reference frequency, and to control the VCO based on the detected phase error such that the base frequency fvco and the reference frequency are coherent; and
a plurality of frequency dividers configured to provide the first plurality of frequencies based on the base frequency fvco,
wherein the plurality of frequency dividers are coupled to the VCO and the phase/frequency detector and charge pump to form the PLL, the reference frequency is of approximately 66 MHz, and the base frequency fvco is of approximately 12,672 MHz.

18. The UWB terminal according to claim 11, wherein:
the reference frequency is approximately 66 MHz; and
the base frequency fvco is approximately 12,672 MHz.

19. The UWB terminal according to claim 11, wherein the first plurality of frequencies include (½)*fvco, (¼)*fvco, (⅛)*fvco, ( 1/16)*fvco, and ( 1/24)*fvco.

20. The UWB terminal according to claim 11, wherein the UWB frequency synthesizer is implemented as a large-scale integration (LSI) device.
